(19) United States
(12) Patent Application Publication
(10) Pub. No.: US 2007/0121965 A1
(43) Pub. Date: May 31, 2007

(54) Automatic audio signal dynamic range adjustment

(75) Inventors: Rani Mary Joseph, Vildhoven (NL); Piotr Leszek Sawicki, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V.

(21) Appl. No.: 10/586,939

(22) PCT Filed: Jan. 25, 2005
(86) PCT No.: PCT/IB05/50293

§ 371 Date: Jul. 24, 2006

Related U.S. Application Data
(60) Provisional application No. 60/539,724, filed on Jan. 28, 2004.

(51) Int. Cl. H03G 3/00

(52) U.S. Cl. 381/104

(57) ABSTRACT

A sound source receives an input audio signal and a sense signal depending on an external condition. The sound source has dynamic range controller that automatically adjusts the dynamic range of the input audio signal to provide the output audio signal, the adjusting depending on the sense signal. Then the sound source converts the output audio signal to ambient sound waves.

The invention herein is related to the field of automated processing of audio signal and more specifically to the field of dynamic range compression/expansion of audio signals.

Dynamic range is the ratio of a specified maximum level of a parameter, such as power, current, voltage, or frequency to the minimum detectable level of that parameter. In the field of audio signal processing the term dynamic range usually refers to the dynamic range of the power level usually referred to as signal level. The signal level is usually measured in decibels (dB) and dynamic range is usually expressed as the difference in dBs between the maximum signal level and the minimum signal level. In this application dynamic range will refer to the difference in signal level expressed in dbs.

The dynamic range of human hearing, the difference between the softest sound we can perceive and the loudest we can comfortably hear, is about 120 dB. The dynamic range typically provided by vinyl records is around 55 dB. The dynamic range available for CD's is around 90 dB and the dynamic range for DVD is about 120 dB.

Compressors, expanders, and noise gates are audio signal processing devices used to alter the dynamic range. This is often done to achieve a more consistent sound when recording, or to provide a special effect to make music sound louder without increasing the maximum volume level. Compressors work by providing higher signal gain to lower level signals in order to reduce dynamic range. Compression increases the loudness of quieter portions of a performance and/or quiets the louder portions. Expanders are the opposite of compressors. Expanders make quiet portions of audio quieter and/or loud portions louder in order to increase the dynamic range. Noise gates reduce dynamic range by truncating or cutting off lower level signals.

Analog broadcasters usually compress the dynamic range of audio because of legal limits on the maximum volume of the broadcast and the high level of noise in analog broadcasting. Receivers for analog broadcasts, commonly use a noise gate to truncate the lower portions of the dynamic range of the signal in order to reduce noise. Some analog receivers have also included expanders to expand the dynamic range of the received signal.

In digital broadcasting, compression and noise gates are not required since there are no volume limitations and transmission noise does not result in noise in the decoded audio signal. However, digital broadcasters continue to compress audio in order to maintain the same sound as analog broadcast and because many listeners are in noisy environments or are listening at a relatively low volume.

It has long been recognized that users generally want more control over various aspects of sound quality. Even some of the earliest audio equipment provided user control over volume. When stereo sound was first developed users were immediately given separate control over the volume of the left and right channels. Later audio equipment provided user control over treble and base settings and surround sound usually provides control over volume of front and back speakers.

Those skilled in the art are directed to the following citations which are hereby incorporated in whole by reference. Published US patent application US2003/0002659 A1 by Adoram Erell, published Jan. 2, 2003 discloses a telephone in which the dynamic range of the sound provided by the loudspeaker of a telephone is adjusted depending on the noise in the audio signal received from the microphone of the telephone. US published application US2001/0055400 A1 discloses dynamic range compression depending on volume setting of audio equipment in an automobile.

While it is known that optimal dynamic range of sound provided by a loudspeaker may depend on ambient noise or signal levels, the inventors have discovered that it is useful to control the dynamic range for a loudspeaker depending on other conditions that are at least partially independent of ambient noise level or volume settings.

The inventors have also discovered that automatic control of dynamic range is required because the audience of a audio performance is generally not aware of the need to adjust the dynamic range. That is, while users of audio equipment prefer one dynamic range setting over another dynamic range setting, it is not obvious to the user that the dynamic range needs to be adjusted or whether it should be increased or decreased. In the invention herein the dynamic range of an audio signal is automatically adjusted, for example, depending on ambient or external conditions.

In one aspect of the invention, a sound source receives an input audio signal and a sense signal depending on an ambient condition independent of sound. The sound source has dynamic range controller that automatically adjusts the dynamic range of the input audio signal to provide the output audio signal, the adjusting depending on the sense signal. Then the sound source converts the output audio signal to ambient sound waves.

The input signal may be a tuner for providing a baseband audio signal from a modulated broadcast signal from cable, satellite or antenna; a reader for providing the audio signal from a record carrier; or a local area network connection. The automatic dynamic range controller may provide continuous adjustment, for example, proportional to the sense signal. Alternatively, the automatic dynamic range controller my provide discrete adjustments depending on predetermined levels of the sense signals, for example, an on/off adjustment depending on a threshold level.

The ambient condition independent of sound, may be for example, the time of day, the ambient light level, the location of the sound source, the acoustic properties at the location of the sound source, and when the sound waves represent music, the genre of the music.

In another aspect of the invention, a sound source receives an input audio signal and at least two sense signals. One sense signal depends on the ambient sound noise level, and the other sense signal depends on a different condition such as a sound volume setting of the sound source. The sound source has dynamic range controller that automatically adjusts the dynamic range of the input audio signal to provide the output audio signal, the adjusting depending on both of the sense signals. Then the sound source converts the output audio signal to ambient sound waves.

Additional aspects and advantages of the invention will become readily apparent to those skilled in the art from the detailed description below with reference to the following drawings.

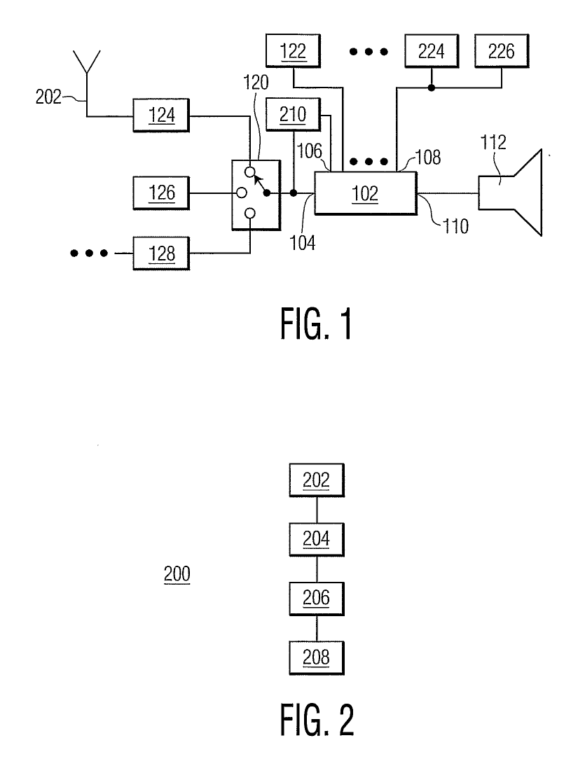

FIG. 1 illustrates a specific example embodiment of the sound source invention herein.

FIG. 2 illustrates a specific example embodiment of the method of the invention herein for adjusting the dynamic range of provided sound waves.

In FIG. 1, a portable sound source 100 includes a dynamic range controller 102. Such portable sound sources include AM/FM radios, CD and DVD players, television sets, vehicle audio systems, and MP3 layers. The dynamic range controller receives an audio input signal at input terminal 104 and receives sense signals at one or more sense terminals 106-108, and adjusts the dynamic range of the audio input signal depending on the sense signals to provide an audio output signal at output terminal 110. The audio output signal is directed to a loudspeaker 112 to convert the audio output signal to sound waves. The dynamic range controller may be a combination of one or more of a dynamic range compressor, a dynamic range expander, or a noise gate. Loudspeaker 112 may be any device for converting the output audio signal to sound waves. The loudspeaker may be mono, stereo, or surround sound, and may include multiple speaker types such as tweeters, horns, woofers or solid state sound devices. Input terminal 104 is connected through a switch 120 to an audio signal input. A well known example of an audio signal input includes antenna 122 and demodulator/tuner 124. The antenna may be a radio antenna for receiving terrestrial broadcasts or a satellite antenna. Well known examples of such inputs include cellular telephone systems, AM/FM radio, television broadcasts, or a wireless network. Alternatively, the input may be a memory device reader 206 such as a CD, DVD, hard disc drive, or a solid state memory cartridge interface. Also, the input may be a connection 208 to a wired network such as a connection to a CATV system, telephone system, or computer network.

Sensor inputs 106-108 receive sensor signals from sensors 210-216. The ellipses in the figure indicate that additional sensors may be provided. Herein, sensor has a very broad meaning. The sensors may be anything that detects or determines a condition such as ambient, external or internal conditions. For example, a sensor might be a clock 212 to provide the time-of-day, or multiple microphones 214 and 216 to detect ambient sound levels or a processor 210 to determine the dynamic range of the input audio signal. Additional detectors may include ambient light sensors, location sensors such as GPS, a network detection sensor (for example, to determine when the sound source in inside an automobile), or a sensor that determines the acoustic properties of the location of the sound source. In the case of processor 210, the processor may detect the power level of the input audio signal or it may detect information in the audio signal such as the genre of music in the signal. The sensors may be communication devices which, for example, receive a code from a radio or infra-red remote control signal to identify the audience and the sensor may provide a sense signal indicating the preferences of the audience with regard to dynamic range.

In FIG. 2 an example 200 of the method of the invention is illustrated. In step 202 an input audio signal is received. In step 204 a sense signal is received. The sense signal may be dependent on any ambient or external condition that is independent of ambient noise or sound volume. In step 206 the dynamic range of the input audio signal is adjusted to provide an output audio signal, the adjusting depending on the sense signal. In step 208, the output audio signal is converted to sound waves, for example, by a loudspeaker.

The above description merely illustrates the present invention and should not be construed as limiting the appended claims to any particular embodiment or group of embodiments. Thus, while the present invention has been described in particular detail with reference to specific example embodiments, it should be appreciated that numerous modifications and changes may be made thereto without departing from the broader and intended spirit and scope of the invention as set forth in the following claims. The specification and drawings are accordingly to be regarded as merely illustrative and not to limit the scope of the appended claims. In interpreting the appended claims, it should be understood that:

a) the word “comprising” does not exclude the presence of additional elements or acts than those listed in a given claim;

b) the word “a” or “an” preceding an element does not exclude the presence of a plurality of such elements;

c) any reference signs in the claims do not limit their scope;

d) several “means” may be represented by the same item or hardware or software implemented structure or function; and

e) each of the disclosed elements may be comprised of hardware portions (e.g., discrete electronic circuitry), software portions (e.g., computer programming), or any combination thereof.

1. A sound source, comprising:
an input (104) for receiving an input audio signal;
an input (106) for receiving a sense signal depending on an ambient condition independent of sound; and
a dynamic range control (102) that automatically adjusts the dynamic range of the input audio signal to provide an output audio signal, the adjusting depending on the sense signal; and
a loudspeaker (112) that converts an output audio signal to ambient sound waves.

2. The sound source of claim 1, wherein:
the input is selected from one or more of: a demodulator/tuner (124)for providing a baseband audio signal from a modulated broadcast signal from cable, satellite or antenna; a reader (206) for providing the audio signal from a record carrier; and a network connection (208).

3. The sound source of claim 1, wherein the dynamic range adjustment is switched between discrete predetermined levels of dynamic range adjustment depending on the sense signal.

4. The sound source of claim 3, wherein depending on the sense signal, in some cases the dynamic range of the output signal is identical to the dynamic range of the input signal and in other cases the dynamic range of the output signal is substantially less than the dynamic range of the input signal.

5. The sound source of claim 1, wherein the automatic dynamic range control provides substantially continuous variation in the level of adjustment of the dynamic range of the output audio signal depending on substantially continuous variations in the sense signal.

6. The sound source of claim 1 wherein the sound independent ambient condition is a time of day.

7. The sound source of claim 1 wherein the sound independent ambient condition is the ambient light level.

8. The sound source of claim 1 wherein the input audio signal is music and the sound independent ambient condition is the genre of the music.

9. The sound source of claim 1 wherein the sound independent ambient condition is the location of the sound source.

10. The sound source of claim 1 wherein the sound independent ambient condition is the acoustic properties at the location of the sound source.

11. The sound source of claim 1 wherein multiple sensors provide one or more sense signals depending on multiple ambient conditions and the dynamic range control adjusts the dynamic range depending on the one or more sense signals.

12. A method, comprising:
receiving an input audio signal;
receiving a sense signal depending on an ambient condition independent of sound;
automatically adjusting the dynamic range of the input audio signal to provide an output audio signal, the adjusting depending on the sense signal; and
converting the output audio signal to ambient sound waves.

13. An sound source, comprising:
an input for receiving an input audio signal;
an input for receiving a first sense signal depending on a condition, the condition being an ambient sound noise level;
an input for receiving a second sense signal depending on another different condition;
a dynamic range control that automatically adjusts the dynamic range of the input audio signal to provide an output audio signal, the adjusting depending on the first and the second sense signals; and
a loudspeaker for converting the output audio signal to ambient sound waves.

14. The sound source of claim 13, wherein the other condition is related to sound.

15. The sound source of claim 13, wherein the other different condition is a volume setting of the sound source.

16. The sound source of claim 13, wherein the other different condition is the dynamic range of the input audio signal.

17. A sound source, comprising:
an input for receiving an input audio signal;
an input for receiving a sense signal depending on an external condition independent of sound; and
an dynamic range control that automatically adjusts the dynamic range of the input audio signal to provide an output audio signal, the adjusting depending on the sense signal; and
a loudspeaker that converts an output audio signal to ambient sound waves.

18. The sound source of claim 17, wherein the sound independent external condition is the identity of the audience.

19. The sound source of claim 17 wherein the sound independent external condition is distance between a loudspeaker and an audience.

20. The sound source of claim 17 wherein the sound independent external condition is the location of the sound source.

21. The sound source of claim 17 wherein the sound independent external condition is the source of the input audio signal.
